(19) United States
(12) Patent Application Publication
(10) Pub. No.: US 2010/0053404 A1
(43) Pub. Date: Mar. 4, 2010

(54) CHARGE-TRANSFER APPARATUS, METHOD FOR DRIVING CHARGE-TRANSFER APPARATUS, AND IMAGING APPARATUS

(75) Inventors: Hirokazu Shiraki, Miyagi (JP); Makoto Kobayashi, Miyagi (JP)

Correspondence Address: KIMBLE INTELLECTUAL PROPERTY LAW, PLLC, 1701 PENNSYLVANIA AVE., NW, SUITE 300, WASHINGTON, DC, 20006, US

(73) Assignee: FUJIFILM Corporation, Tokyo (JP)

(21) Appl. No.: 12/548,391

(22) Filed: Aug. 26, 2009

(30) Foreign Application Priority Data
Aug. 26, 2008 (JP) 2008-216849

(51) Int. Cl. H04N 5/335; H01L 27/148

(52) U.S. Cl. 348/311; 257/239; 257/E27.15; 348/E05.091

(57) ABSTRACT

Driving is performed so that a transition start time point ta of drive pulse signals φH1 and φH2 which are applied to transfer electrodes of a charge transfer section on an upstream side of a branch section is within transition period B or C of drive pulse signals φHP1 and φHP2 which are applied to transfer electrodes of the charge transfer section on a downstream side.

### CROSS-REFERENCE TO RELATED APPLICATIONS

This application claims the benefit of Japanese Patent Application No. 2008-216849, filed Aug. 26, 2008, the entire contents of which are hereby incorporated by reference, the same as if set forth at length.

### BACKGROUND OF THE INVENTION

1. Technical Field

The present invention relates to a charge-transfer apparatus for transferring charges through a branch, a method for driving the charge-transfer apparatus, and an imaging apparatus equipped with the charge-transfer apparatus for transferring charges through the branch.

2. Description of Related Art

JP 2006-269969 A (corresponding to US 2006/0214194 A) and JP 2007-201160 A (US 2008/0030607 A) describes, as a charge-transfer device being used for a charge transfer section of a CCD solid-state imaging device, devices in which its transfer channel is branched into two portions at an downstream end portion thereof in a charge transfer direction. In the branch section of the charge-transfer device having such two-branched output path as described above, signal charges are distributed alternately to the two branch paths and used for operation. Hence, an operation frequency of its output circuit section for outputting output signals according to the charge signals, which are transferred through the branch section, can be made half an operation frequency of an output circuit section in the case that the transfer channel is not branched.

In the charge-transfer devices described in JP 2006-269969 A and JP 2007-201160 A, the frequency of drive pulse signals in a transfer region thereof after branching is half the frequency of drive pulse signals in a transfer region before branching. On the other hand, the frequency of the transfer from the branch region of the transfer region before branching to the two branched channels (the transfer regions after branching) is set to the frequency of the drive pulse signals before branching. However, the shape of the branch region serving as a region connected to the branched channels is inevitably different from the shape of the channel before branching. It is thus unavoidable that the transfer efficiency of charge transfer from the branch region to the two branched channels is low in comparison with the transfer efficiency of charge transfer before branching.

In the charge-transfer device described in JP 2006-269969 A, an electrode in the branch region (the last electrode among electrodes to which the drive pulse signals for the transfer region before branching are supplied) is formed into an approximately triangular shape. Hence, the charge to be transferred is collected at a central portion of the channel, and the efficiency of transferring the charge from the branch region to the branched channels is improved.

In addition, in the charge-transfer device described in JP 2007-201160 A, a stepwise potential being high on the upstream side and low on the downstream side of the branch region is formed, and a constant voltage is applied to branch region electrodes formed above the branch region, and driving is performed so that charge does not stagnate in the branch region during charge transfer. Hence, the time for charge transfer to the branch paths is effectively lengthened to improve the efficiency of charge transfer. However, an influence on the charge transfer due to the timing difference in drive pulse signals has not been examined.

### SUMMARY OF THE INVENTION

The invention has been made in view of the above circumstances, and provides a charge-transfer apparatus, a charge transfer method and an imaging apparatus that are improved in the efficiency of charge transfer at a time when charge is transferred through a branch.

According to an aspect of the invention, a charge-transfer apparatus for transferring charges through a branch includes a channel region, a plurality of charge transfer electrodes and a drive section. The channel region is formed on a semiconductor substrate. The plurality of charge transfer electrodes are provided continuously in an extending direction of the channel region above the channel region. The drive section supplies drive signals to the charge transfer electrodes. The channel region includes a first region, a branch region, a second region and a third region. The first region is on an upstream side in a charge transfer direction. The branch region is adjacent to the first region and is on a downstream side of the first region in the charge transfer direction. The second region and the third region are branched from the branch region. The branch region has a potential being shallow on the upstream side in the charge transfer direction and deep on the downstream side in the charge transfer direction. The drive section supplies first drive pulse signals, acting as two-phase clock pulse signals having opposite phases and a predetermined period, to the charge transfer electrodes above the first region. The drive section supplies a predetermined fixed voltage signal to the charge transfer electrodes above the branch region. The drive section supplies second drive pulse signals, having a period twice as long as the period of the first drive pulse signals, to the charge transfer electrodes above the second region and the charge transfer electrodes above the third region. The drive section supplies the second drive pulse signals having opposite phases to (i) the charge transfer electrodes above the second region adjacent to the charge transfer electrodes above the branch region and (ii) the charge transfer electrodes above the third region adjacent to the charge transfer electrodes above the branch region. When the charge in the first region is transferred to the branch region, a transition start time point of the first drive pulse signals is within a transition period of the second drive pulse signals.

According to another aspect of the invention, there is provided a drive method for driving a charge-transfer apparatus. The charge-transfer apparatus includes a channel region and a plurality of charge transfer electrodes. The channel region is formed on a semiconductor substrate. The plurality of charge transfer electrodes are provided continuously in an extending direction of the channel region above the channel region. The channel region includes a first region, a branch region, a second region and a third region. The first region is on an upstream side in a charge transfer direction. The branch region is adjacent to the first region and is on a downstream side of the first region in the charge transfer direction. The second region and the third region are branched from the branch region. The branch region has a potential being shallow on the upstream side in the charge transfer direction and deep on the downstream side in the charge transfer direction. The method includes: supplying first drive pulse signals, acting as two-phase clock pulse signals having opposite phases and a predetermined period, to the charge transfer electrodes above the first region; supplying a predetermined fixed voltage signal to the charge transfer electrodes above the branch region; supplying second drive pulse signals, having a period twice as long as the period of the first drive pulse signals, to the charge transfer electrodes above the second region and the charge transfer electrodes above the third region; and supplying the second drive pulse signals, having opposite phases, to (i) the charge transfer electrodes above the second region adjacent to the charge transfer electrode above the branch region and (ii) the charge transfer electrodes above the third region adjacent to the charge transfer electrode above the branch region. When the charge in the first region is transferred to the branch region, a transition start time point of the first drive pulse signals is within a transition period of the second drive pulse signals.

According to further another aspect of the invention, an imaging apparatus includes the above-mentioned charge transfer apparatus.

The present invention can provide a charge transfer apparatus and a charge transfer method improved in the efficiency of charge transfer at the time when charge is transferred through the branch. When an imaging apparatus including the above-described charge transfer apparatus is used to transfer signal charges which are obtained by photoelectric-conversion using plural photodiodes two-dimensionally or one-dimensionally arranged, image flowing sideways and resolution degradation can be prevented. Furthermore, when an attempt is made to obtain color signals by providing color filters above the photodiodes, excellent images can be obtained while preventing the generation of color false signals.

### BRIEF DESCRIPTION OF THE DRAWINGS

FIG. 1 is a view showing the schematic configuration of a solid-state imaging device, for explaining an embodiment of the present invention;

FIG. 2 is a partly enlarged view showing a horizontal charge transfer section of the solid-state imaging device shown in FIG. 1;

FIG. 3 is a schematic sectional view taken along line A1-A2-A3-A4 in the horizontal charge transfer section shown in FIG. 2;

FIG. 4 is a view showing change in potential of a channel along the line A1-A2-A3-A4 in the horizontal charge transfer section shown in FIG. 2;

FIG. 5 is a graph showing rough timings of drive pulse signals in the horizontal charge transfer section of the solid-state imaging device shown in FIG. 1;

FIG. 6 is a graph showing examples of detailed timings of the drive pulse signals shown in FIG. 5;

FIGS. 7A and 7B are views schematically showing charge transfer when the horizontal charge transfer section of the solid-state imaging device shown in FIG. 1 are driven using the drive pulse signals shown in FIG. 5;

FIG. 8 is a graph showing another example of the detailed timings of the drive pulse signals for the horizontal charge transfer section of the solid-state imaging device shown in FIG. 1;

FIG. 9 is a graph showing still another example of the detailed timings of the drive pulse signals for the horizontal charge transfer section of the solid-state imaging device shown in FIG. 1;

FIG. 10 is a graph illustrating generation timings of the drive pulse signals shown in FIGS. 5 and 6; and

FIG. 11 is a graph illustrating generation timings of the drive pulse signals shown in FIG. 9.

### DETAILED DESCRIPTION OF EMBODIMENTS OF THE INVENTION

Embodiments of the present invention will be described below with reference to the accompanying drawings.

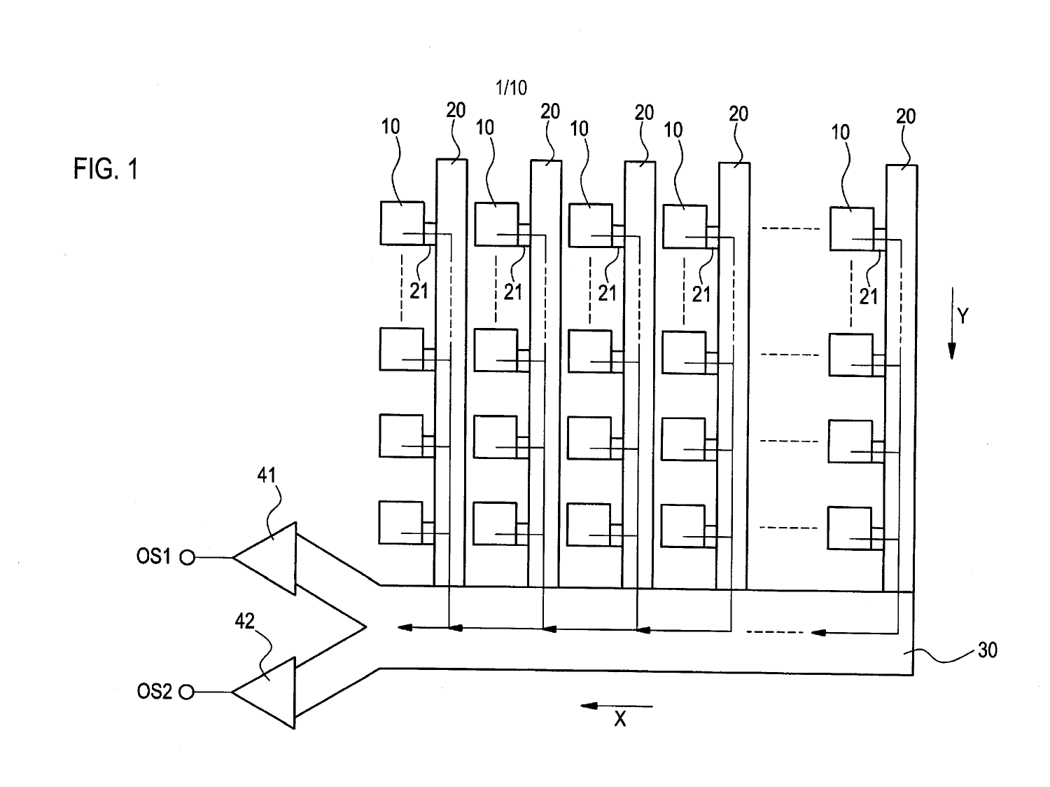

FIG. 1 is a view showing the schematic configuration of a solid-state imaging device, for explaining an embodiment of the present invention. The solid-state imaging device shown in FIG. 1 includes plural photoelectric conversion elements 10, plural vertical transfer sections 20, a horizontal transfer section 30 and output sections 41 and 42. The plural photoelectric conversion elements 10 are arranged on the surface of a semiconductor substrate in a grid so as to have plural rows and plural columns. The plural vertical transfer sections 20 are provided adjacent to the photoelectric conversion elements 10. The plural vertical transfer sections 20 transfer charges generated in the photoelectric conversion elements 10, in a column direction Y. The horizontal transfer section 30 transfers the charges, which are transferred from the vertical transfer sections 20, in a row direction X. The output sections 41 and 42 output signals according to the charges transferred by the horizontal transfer section 30. In FIG. 1, reference numerals are given only a part of the photoelectric conversion elements 10 and only a part of charge reading sections 21.

The photoelectric conversion elements 10 are implemented by embedded-type photodiodes, and generate charges according to an amount of incident light and accumulate the charges therein. If the solid-state imaging device is one for taking a color image, a color filter (not shown) is provided above each of the photoelectric conversion elements 10, and each photoelectric conversion element 10 generates charges in accordance with the spectral sensitivity corresponding to the color of the filter and accumulates the charges. The color filters have the three primary colors of red, green and blue.

Each vertical transfer section 20 includes a charge-transfer device having a vertical transfer channel for accumulating and transferring the charges read from the photoelectric conversion elements 10 and vertical transfer electrodes which are provided above the vertical transfer channel (in FIG. 1, regions corresponding to the vertical transfer channel regions are schematically shown as the vertical transfer sections 20). The charges of the photoelectric conversion elements 10 are read out to the vertical transfer section 20 via charge reading sections 21. Since various shapes and arrangements of the photoelectric conversion elements 10, the vertical transfer sections 20 and the charge reading sections 21 and various shapes, arrangements, etc. of the vertical transfer electrodes (not shown) are known, detailed descriptions thereof will be omitted.

The horizontal transfer section 30 includes a charge-transfer device having a horizontal transfer channel for accumulating and transferring the charges transferred from the vertical transfer sections 20 and horizontal transfer electrodes which are provided above the horizontal transfer channel (in FIG. 1, a region corresponding to the horizontal transfer channel region is schematically shown as the horizontal transfer section 30). As described later in detail, a horizontal transfer channel region of the horizontal transfer section 30 on a downstream side in a charge transfer direction is branched into two portions, and the charges are distributed and transferred to the two output sections 41 and 42. Although FIG. 1 shows the configuration in which the charges are directly transferred from the vertical transfer section 20 to the horizontal transfer section 30, such a configuration may be adopted in which a line memory for temporally accumulating the transferred charges is provided in an end portion of each vertical transfer section 20 on the horizontal-transfer-section side. In this case, the charges may be selectively transferred to the horizontal transfer section 30 from the line memories.

The output sections 41 and 42 are used to output voltage signals OS1 and OS2 in accordance with the charges transferred from the horizontal transfer section 30. Each of the output sections 41 and 42 is configured so as to have a floating diffusion region, a reset transistor and a source follower amplifier. Since the output sections having this kind of configuration are known, a description thereof will be omitted.

When an image is taken using the solid-state imaging device shown in FIG. 1, drive signals are supplied from a drive section (not shown). The charges, which are generated in the photoelectric conversion elements 10 according to an amount of incident light, are read out to the vertical transfer sections 20 and transferred from the vertical transfer sections 20 to the horizontal transfer section 30. Then, the charges are output from the output sections 41 and 42 as image signals. The drive signals supplied from the drive section include drive pulse signals to be supplied to the vertical transfer electrodes and the horizontal transfer electrodes.

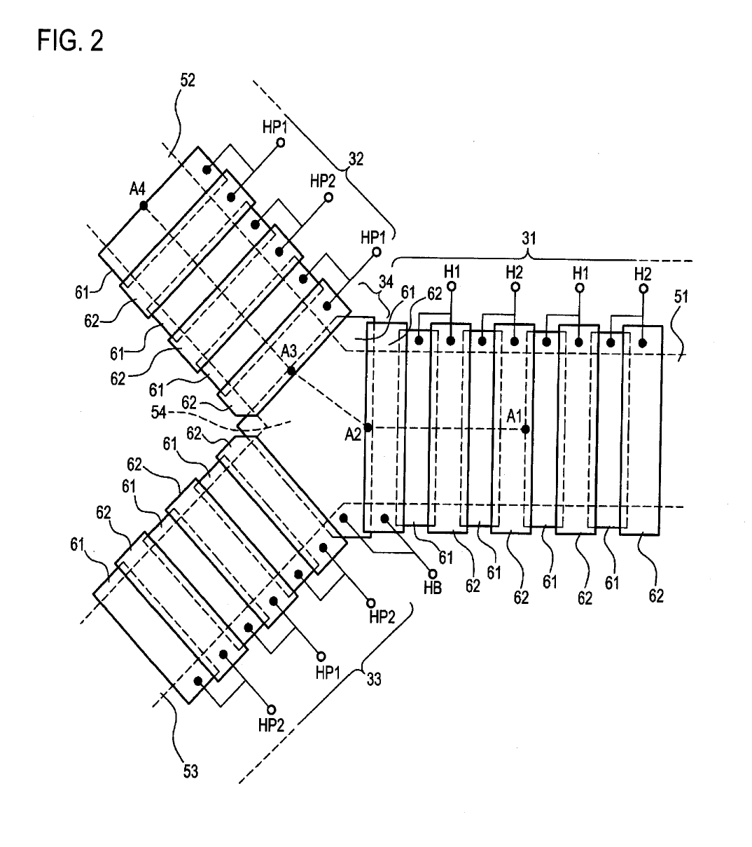

FIG. 2 is a partly enlarged view showing the horizontal transfer section 30 of the solid-state imaging device shown in FIG. 1. The horizontal transfer section 30 includes a first horizontal transfer section 31, a second horizontal transfer section 32, a third horizontal transfer section 33 and a branch section 34. FIG. 2 is an enlarged view of a portion near the branch section 34. The first horizontal transfer section 31 is disposed on the most upstream side in the charge transfer direction, receives the charges in parallel from the vertical transfer sections 20 and sequentially transfers the charges to the branch section 34. The branch section 34 distributes the charges transferred from the first horizontal transfer section 31 to transfer the charges to the second horizontal transfer section 32 or the third horizontal transfer section 33.

The horizontal transfer section 30 is formed on a semiconductor substrate and is equipped with (i) a channel region serving as a path in which charges are accumulated and moved and (ii) horizontal transfer electrodes (hereafter which may be simply referred to as “transfer electrodes”) disposed above the channel region. The channel region includes a first channel region 51 corresponding to the first horizontal transfer section 31, a second channel region 52 corresponding to the second horizontal transfer section 32, a third channel region 53 corresponding to the third horizontal transfer section 33, and a branch region 54 corresponding to the branch section 34. The transfer electrodes include plural first polysilicon electrodes 61 and plural second polysilicon electrodes 62 which are formed between the first polysilicon electrodes 61 so as to overlap the first polysilicon electrodes 61. A drive voltage having a certain potential is applied to the first polysilicon electrode 61 and the second polysilicon electrode 62, which are adjacent to each other (hereafter, the pair of electrodes to which the drive voltage having the same potential is applied may be referred to as “transfer electrode pair”). Hereafter, when the channel region provided for the horizontal transfer section 30 is described without the first channel region 51, the second channel region 52, the third channel region 53 and the branch region 54 being differentiated, the channel regions may be simply referred to as the “channel region 50”. When the transfer electrodes provided for the horizontal transfer section 30 are described without the first polysilicon electrodes 61 and the second polysilicon electrodes 62 being differentiated, the transfer electrodes may be simply referred to as “horizontal transfer electrodes 60”.

In the first horizontal transfer section 31, two-phase clock pulse signals (first drive pulse signals) having opposite phases and a predetermined period are supplied to every other transfer electrode pair. In the second horizontal transfer section 32 and the third horizontal transfer section 33, two-phase clock pulse signals (second drive pulse signals) having a period twice as long as the period of the first drive pulse signals are supplied to every other transfer electrode pair. Also, a fixed voltage is applied to the transfer electrode pair of the branch section 34.

FIG. 2 shows that one of the first drive pulse signals is supplied to terminals H1 and the other first drive pulse signal is supplied to terminals H2, and that one of the second drive pulse signals is supplied to terminals HP1 and the other second drive pulse signal is supplied to terminals HP2. As shown in FIG. 2, the terminal HP1 is connected to the transfer electrode pair of the second horizontal transfer section 32 adjacent to the branch section 34, and the terminal HP2 is connected to the transfer electrode pair of the third horizontal transfer section 33 adjacent to the branch section 34. Hence, the second drive pulse signals having the phases opposite to each other (opposite phases) are respectively supplied to the transfer electrode pair of the second horizontal transfer section 32 adjacent to the branch section 34 and to the transfer electrode pair of the third horizontal transfer section 33 adjacent to the branch section 34. Furthermore, the fixed voltage is applied from a terminal HB to the transfer electrode pair of the branch section 34.

FIG. 2 also schematically shows that the drive signals (the first drive pulse signals, etc.) are supplied via the terminals H1, H2, HP1, HP2 and HB. Specifically, the drive signals are supplied using drive signal supplying wirings (not shown) connected to the horizontal transfer electrodes 60 corresponding to the terminals.

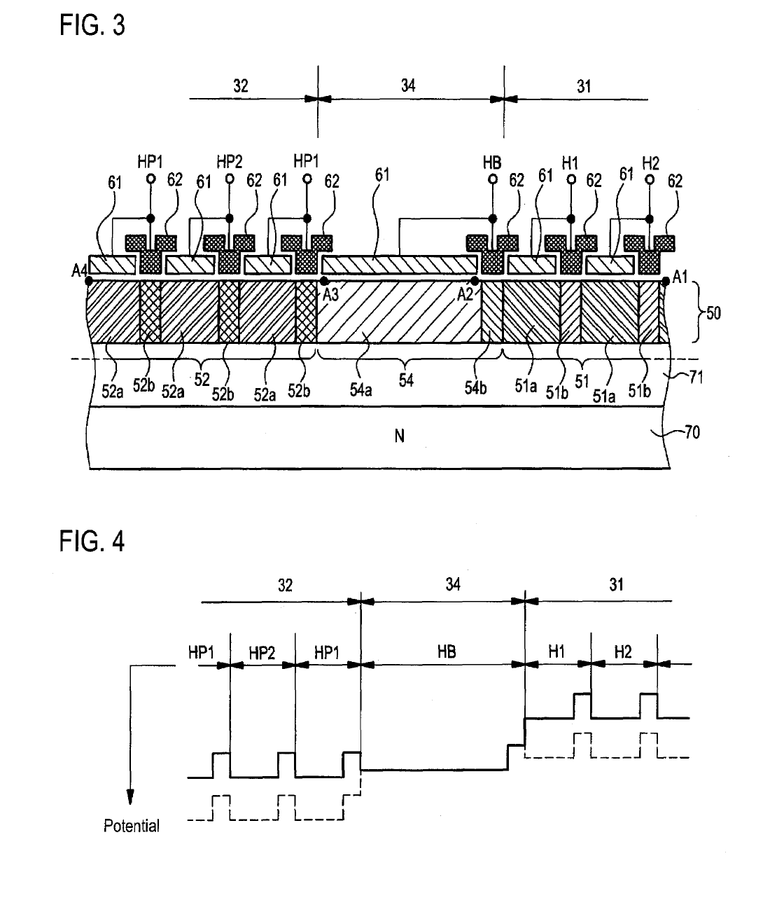

FIG. 3 is a schematic sectional view taken along a line A1-A2-A3-A4 in the horizontal charge transfer section shown in FIG. 2. The channel region 50 of the horizontal transfer section 30 is an N-type impurity region formed inside a P-well 71 formed in an N-type silicon substrate 70. In the first channel region 51, plural relatively-high-concentration impurity regions 51a and plural relatively-low-concentration impurity regions 51b are disposed alternately in the transfer direction. In the second channel region 52, plural relatively-high-concentration impurity regions 52a and plural relatively-low-concentration impurity regions 52b are disposed alternately in the transfer direction. In the branch region 54, a relatively-high-concentration impurity region 54a and a relatively-low-concentration impurity region 54b are disposed.

As clearly shown in FIG. 3, the relatively-high-concentration impurity regions 51a, 52a and 54a are disposed below the first polysilicon electrodes 61, and the relatively-low-concentration impurity regions 51b, 52b and 54b are disposed below the second polysilicon electrodes 62. Furthermore, among the relatively-high-concentration impurity regions 51a, 52a and 54a, the region 51a has the lowest impurity concentration, the region 54a has the second lowest impurity concentration, and the region 52a has the highest impurity concentration. Similarly, among the relatively-low-concentration impurity regions 51b, 52b and 54b, the region 51b has the lowest impurity concentration, the region 54b has the second lowest impurity concentration, and the region 52b has the highest impurity concentration.

Also in the third channel region 53, plural relatively-high-concentration impurity regions (having the same concentration as that of the impurity region 52a) and multiple relatively-low-concentration impurity regions (having the same concentration as that of the impurity region 52b) are disposed alternately in the transfer direction, although they are not shown in the figure.

FIG. 4 is a view showing change in potential at a time when the drive signals are supplied to the channel region 50, along the line A1-A2-A3-A4 in the horizontal charge transfer section shown in FIG. 2. The two-phase drive pulse signals are supplied to the transfer electrodes of the first horizontal transfer section 31, the second horizontal transfer section 32 and the third horizontal transfer section 33, and the fixed voltage is applied to the transfer electrodes of the branch section 34. FIG. 4 shows (i) potentials at a time when the levels of the two-phase drive pulse signals are low, by solid lines and (ii) potentials at a time when the levels of the two-phase drive pulse signals are high, by broken lines. As obviously understood from the change in potential shown in FIG. 4, charges can be accumulated in the relatively-high-concentration impurity regions 51a and 52a. Hence, the charges accumulated in the first horizontal transfer section 31 and the second horizontal transfer section 32 can be transferred sequentially by supplying the two-phase drive pulse signals. In addition, the potential of the impurity region 54a of the branch section 34 is deeper than the potential of the impurity regions 51a of the first horizontal transfer section 31 and shallower than the potential of the impurity regions 52a of the second horizontal transfer section 32. Hence, the charges, which are transferred from the first horizontal transfer section 31 to the branch section 34, are transferred directly to the second horizontal transfer section 32 when the level of the second drive pulse supplied to the terminals HP1 is high. Since the structure of the third horizontal transfer section 33 and the drive pulse signals supplied thereto are similar to the structure of the second horizontal transfer section 32 and the drive pulse signals supplied thereto, respectively, transfer in the third horizontal transfer section 33 is similar to the transfer in the second horizontal transfer section 32.

Distribution/transfer of charges from the first horizontal transfer section 31 to the second horizontal transfer section 32 and the third horizontal transfer section 33 will be described below in more detail. When the level of the first drive pulse signal at the terminals H1 becomes low, the potential of the impurity region 51a of the first horizontal transfer section 31 becomes shallower than the potential of the impurity region 54b of the branch section 34, the charges in the impurity region 51a of the first horizontal transfer section 31 is transferred to the branch section 34. At this time, since the level of one of the second drive pulse signals is high, one of (i) the impurity region 52b of the second horizontal transfer section 32 and (ii) the impurity region 53b of the third horizontal transfer section 33 becomes deeper than the potential of the impurity region 54a of the branch section 34. Hence, the charges, which are transferred to the branch section 34, are transferred to the second horizontal transfer section 32 or the third horizontal transfer section 33 without staying in the branch section 34.

At this time, since the other of (i) the impurity region 52b of the second horizontal transfer section 32 and (ii) the impurity region 53b of the third horizontal transfer section 33 becomes shallower than the potential of the impurity region 54a of the branch section 34, the charges, which are transferred from the first horizontal transfer section 31 to the branch section 34, are only transferred to the one of the second horizontal transfer section 32 and the third horizontal transfer section 33. Moreover, since the potentials of the impurity region 52b of the second horizontal transfer section 32 and the impurity region 53b of the third horizontal transfer section 33 change in accordance with the states of the second drive pulse signals, the charges, which are transferred from the first horizontal transfer section 31 to the branch section 34, are distributed to the second horizontal transfer section 32 or the third horizontal transfer section 33 in accordance with the states of the second drive pulse signals.

In addition, as shown in FIG. 2, it is assumed that a planar shape of the branch region 54 serving as the channel region of the branch section 34 has a approximately triangular or trapezoidal shape portion which becomes narrower in width from the upstream side (on the first horizontal transfer section side) in the charge transfer direction to the downstream side (on he second horizontal transfer section side or the third horizontal transfer section side). In FIG. 2, a portion excluding a portion having the same width as the width of the first channel region 51 and excluding portions having the same width as the width of the second channel region 52 and as the width of the third channel region 53 has an approximately triangular shape. As a result, the potential profile of the branch region 54 slopes down from the second horizontal transfer section 32 side to the third horizontal transfer section 33 side or from the third horizontal transfer section 33 side to the second horizontal transfer section 32 side. Thereby, the efficiency of charge transfer from the branch section 34 to the second horizontal transfer section 32 or the third horizontal transfer section 33 is improved.

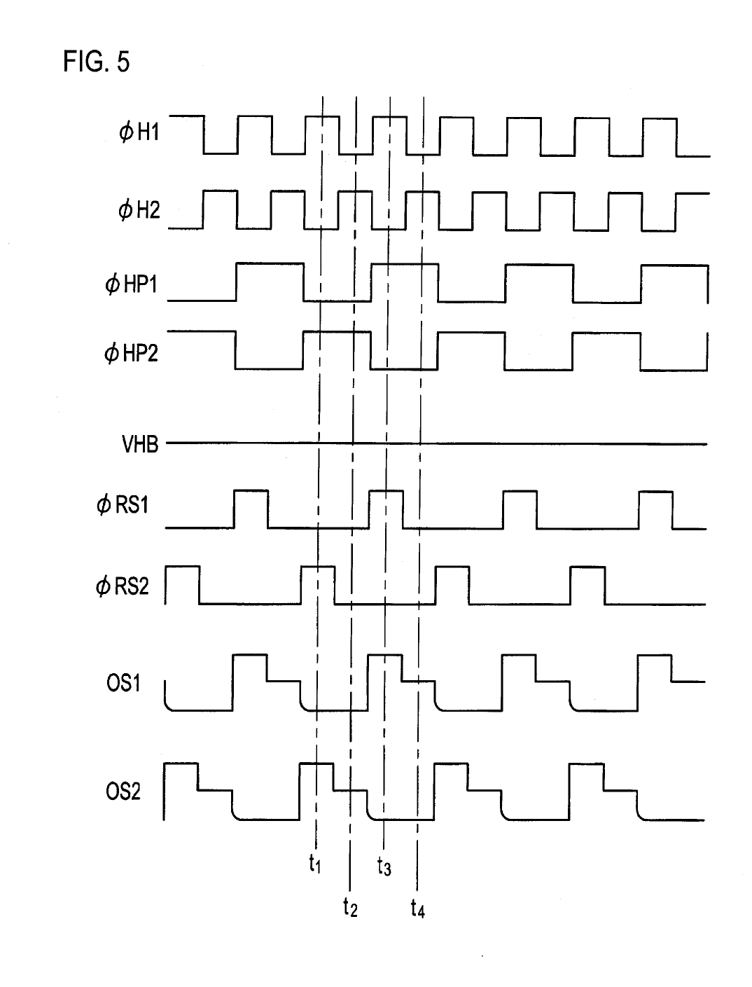

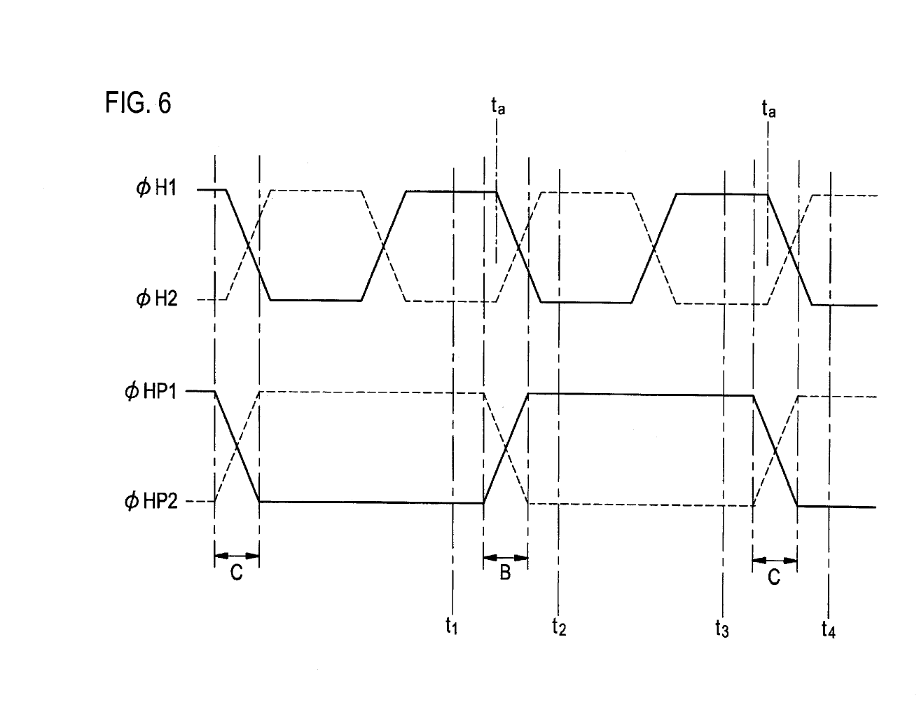

FIG. 5 is a graph showing rough timings of the drive pulse signals in the horizontal charge transfer section of the solid-state imaging device shown in FIG. 1. FIG. 6 is a graph showing examples of detailed timings of the drive pulse signals shown in FIG. 5. The first drive pulse signals φH1 and φH2 respectively supplied to the terminals H1 and H2 shown in FIG. 2 are the two-phase clock pulse signals having the opposite phases and the predetermined period. Furthermore, the second drive pulse signals respectively supplied to the terminals HP1 and HP2 shown in FIG. 2 are the two-phase clock pulse signals having the period twice as long as that of the first drive pulse signals φH1 and φH2. A predetermined fixed voltage VHB is supplied to the terminal HB shown in FIG. 2.

Reset pulse signals φRS1 and φRS2 shown in FIG. 5 are used to reset the reset transistors (not shown) of the output sections 41 and 42, thereby resetting charges in the floating diffusion regions (not shown) from the second horizontal transfer section 32 and the third horizontal transfer section 33. The reset pulse signals φRS1 and φRS2 are synchronous with the second drive pulse signals φHP1 and φHP2, respectively. Hence, voltage signals OS1 and OS2 depending on the charges in the floating diffusion regions change as shown in FIG. 5. As clearly shown in FIG. 5, the voltage signals OS1 and OS2 from the output sections 41 and 42 change with a period which is twice as long as the driving period of the first horizontal transfer section 31. Since the operations of the output sections 41 and 42 are known as described in JP 2006-269969 A and JP 2006-269969 A, detailed descriptions of the operations will be omitted.

FIG. 6 is a graph showing the detailed timings of the first drive pulse signals φH1 and φH2 and the second drive pulse signals φHP1 and φHP2 around time points t1 to t4 shown in FIG. 5. As described with reference to FIGS. 2 to 4, when the level of the first drive pulse signal φH1 changes (transitions) from high to low, the charges accumulated in the impurity region 51a of the first horizontal transfer section 31 adjacent to the branch section 34 is transferred to the branch section 34. In synchronization with this transfer, the second drive pulse signals φHP1 and φHP2 also change (transition), whereby switching is performed between transfer to the second horizontal transfer section 32 and transfer to the third horizontal transfer section 33. The first drive pulse signals φH1 and φH2 and the second drive pulse signals φHP1 and φHP2 are supplied from the drive section (not shown) to the transfer electrodes 60 so that a transition start time point ta of the first drive pulse signal φH1 is within transition periods B and C of the second drive pulse signals φHP1 and φHP2. Herein, the transition period B of the second drive pulse signals φHP1 and φHP2 is a period in which the transfer to the second horizontal transfer section 32 is switched to.

Also, the transition period C of the second drive pulse signals φHP1 and φHP2 is a period in which the transfer to the third horizontal transfer section 33 is switched to.

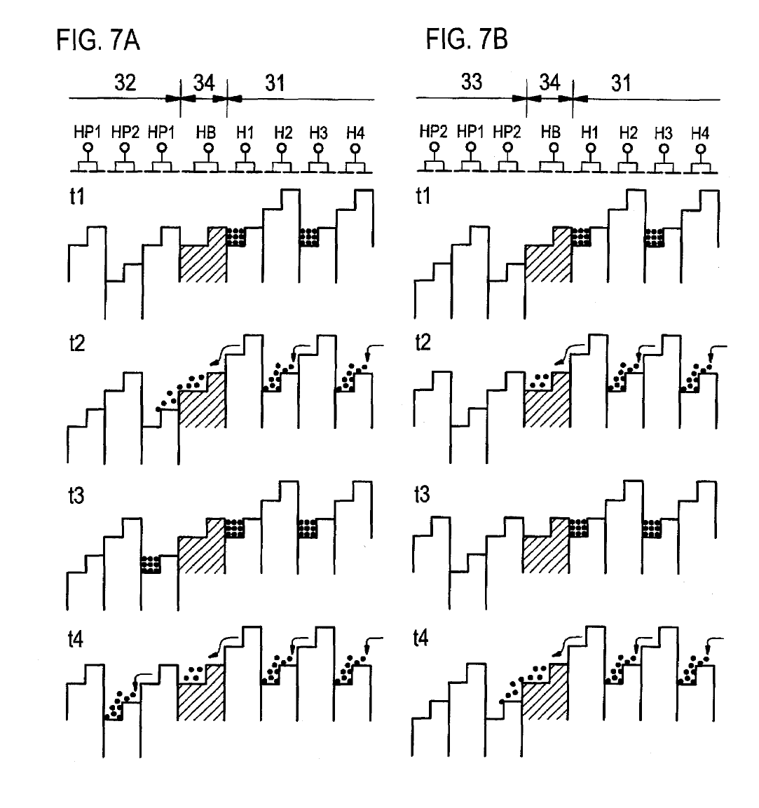

FIGS. 7A and 7B are views schematically showing charge transfer when the horizontal charge transfer section of the solid-state imaging device shown in FIG. 1 are driven using the drive pulse signals shown in FIG. 5. Furthermore, FIGS. 7A and 7B also show (i) change in potential from a state in which charges are accumulated in the impurity regions 51a of the first horizontal transfer section 31 and (ii) the states of the charges, at time points corresponding to the time points t1 to t4 shown in FIG. 5. FIG. 7A shows the states of the second horizontal transfer section 32 side, and FIG. 7B shows the states of the third horizontal transfer section 33 side.

At the time point t1, since the level of the first drive pulse signal φH1 is high, the charges remain held in the first horizontal transfer section 31. At the time point t2, since the level of the first drive pulse signal φH1 has changed to low, the charges are transferred by one transfer step in the first horizontal transfer section 31, and the charges in the impurity region 51a adjacent to the branch section 34 are transferred to the branch section 34. At this time point t2, since the level of the second drive pulse signal φHP1 has changed to high and the level of the second drive pulse signal φHP2 has changed to low, the charges in the branch section 34 are transferred to the second horizontal transfer section 32 without staying in the branch section 34.

At the time point t3, since the levels of the first drive pulse signals φH1 and φH2 have been inverted, the state of the first horizontal transfer section 31 is the same as that at the time point t1. In addition, since the states of the second drive pulse signals φHP1 and φHP2 are the same as those at the time point t2, the charges from the branch section 34 are transferred to the second horizontal transfer section 32 and accumulated in the impurity region 52a adjacent to the branch section 34.

At the time point t4, since the states of the first drive pulse signals φH1 and φH2 are the same as those at the time point t2, the charges are transferred by one transfer step in the first horizontal transfer section 31, and the charges in the impurity region 51a adjacent to the branch section 34 are transferred to the branch section 34. At this time point t4, since the level of the second drive pulse signal φHP2 has changed to high and the level of the second drive pulse signal φHP1 has changed to low, the charges in the branch section 34 are transferred to the third horizontal transfer section 33 without staying in the branch section 34. At the same time, the charges in the second horizontal transfer section 32 are transferred by one transfer step.

The charges transferred along the first horizontal transfer section 31 are alternately distributed to the second horizontal transfer section 32 and the third horizontal transfer section 33 by repeating the above-mentioned operation.

As described with reference to FIG. 6, when the charges accumulated in the impurity region 51a of the first horizontal transfer section 31 adjacent to the branch section 34 are transferred to the branch section 34, the transition start time point ta of the first drive pulse signals φH1 and φH2 is within the transition periods B and C of the second drive pulse signals φHP1 and φHP2. In other words, at the timing when the charges begin to flow from the first horizontal transfer section 31 to the branch section 34, the changes in potentials of the second horizontal transfer section 32 and the third horizontal transfer section 33 on the downstream side have already begun. Furthermore, before the changes in the potentials of the second horizontal transfer section 32 and the third horizontal transfer section 33 complete, the transitions of the first drive pulse signals φH1 and φH2 start.

Hence, the charges transferred to the branch section 34 are securely transferred only to a desired transfer section, that is, either the second horizontal transfer section 32 or the third horizontal transfer section 33.

In addition, since the charges flow from the branch section 34 to the second horizontal transfer section 32 or the third horizontal transfer section 33 even in the transition periods of the second drive pulse signals φHP1 and φHP2, a time in which the charges flow from the branch section 34 to the second horizontal transfer section 32 or the third horizontal transfer section 33 can be made longer. Hence, the charges transferred to the branch section 34 can be securely transferred to the second horizontal transfer section 32 or the third horizontal transfer section 33.

As described above, by supplying the first drive pulse signals and the second drive pulse signals at the timings shown in FIG. 6, the charges transferred from the upstream side (the first horizontal transfer section 31) to the branch section 34 are not transferred to an unintended transfer section on the downstream side (the second horizontal transfer section 32 or the third horizontal transfer section 33) by mistake and are accurately distributed and transferred to the two transfer sections without being mixed with the charges in the subsequent transfer steps.

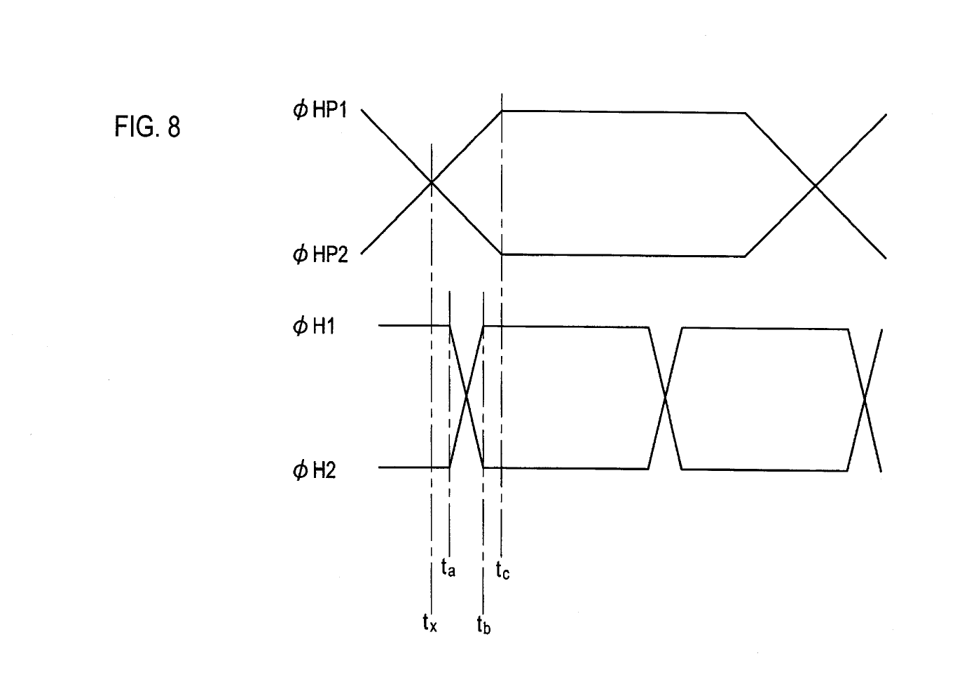

FIG. 8 is a graph showing another example of the detailed timings of the drive pulse signals for the horizontal charge transfer section of the solid-state imaging device shown in FIG. 1. The drive pulse signals shown in FIG. 8 are basically similar to those shown in FIG. 5 but are different in that the transition start time point ta of the first drive pulse signal φH1 is further limited and that a transition completion time point tb the first drive pulse signal φH1 is within the transition period of the second drive pulse signals φHP1 and φHP2. In other words, as shown in FIG. 8, both the transition start time point ta and the transition completion time point tb of the first drive pulse signal φH1 are within the period between a crossover time point tx between the second drive pulse signals φHP1 and φHP2 and a transition completion time point tc of the second drive pulse signals φHP1 and φHP2. When driving is performed at the above-mentioned timings, the transition of the first drive pulse signal φH1 starts after the potentials of the second horizontal transfer section 32 and the third horizontal transfer section 33 which are on the downstream side are inverted, and then the charges from the first horizontal transfer section 31 on the upstream side are transferred to the branch section 34. Hence, at the time when the charges are transferred from the upstream side to the branch section 34, the potentials of the second horizontal transfer section 32 and the third horizontal transfer section 33 on the downstream side have already been inverted. As a result, the charges transferred to the branch section 34 can be transferred to the second horizontal transfer section 32 or the third horizontal transfer section 33 more securely. Moreover, the transition completion time point tb of the first drive pulse signal φH1 is before the transition completion time point tc of the second drive pulse signals φHP1 and φHP2 so that the transition of the first drive pulse signal φH1 completes early. Hence, the transfer time from the first horizontal transfer section 31 to the branch section 34 can be shortened.

As described above, by supplying the first drive pulse signals and the second drive pulse signals at the timings shown in FIG. 8, the charges transferred from the upstream side (the first horizontal transfer section 31) to the branch section 34 are more accurately distributed and transferred to the two transfer sections (the second horizontal transfer section 32 and the third horizontal transfer section 33).

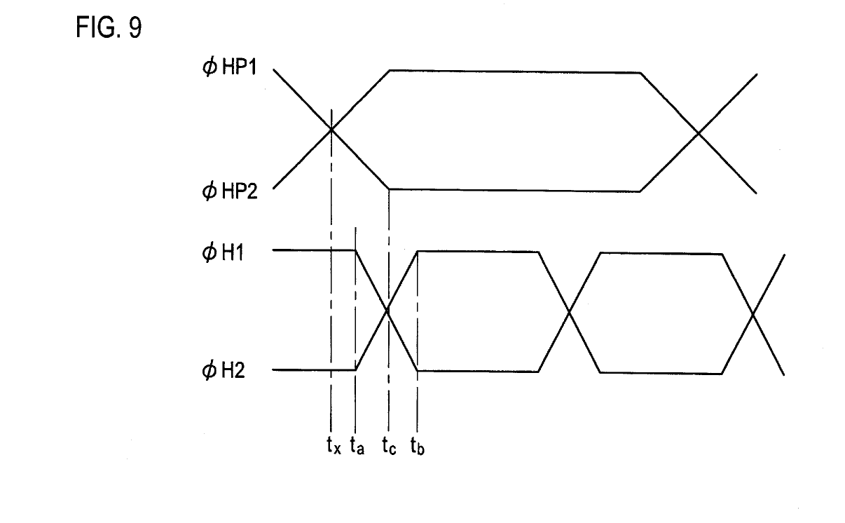

FIG. 9 is a graph showing still another example of the detailed timings of the drive pulse signals for the horizontal charge transfer section of the solid-state imaging device shown in FIG. 1. The drive pulse signals shown in FIG. 9 are basically similar to those shown in FIG. 8 but are different in that the transition completion time point tb of the first drive pulse signal φH1 is after the completion of the transition of the second drive pulse signals φHP1 and φHP2. In other words, the transition start time point ta of the first drive pulse signal φH1 is within the period between (i) the crossover time point tx between the second drive pulse signals φHP1 and φHP2 and (ii) the transition completion time point tc of the second drive pulse signals φHP1 and φHP2, and the transition completion time point tb of the first drive pulse signal φH1 is after the transition completion time point tc of the second drive pulse signals φHP1 and φHP2.

When driving is performed at the above-mentioned timings, as in the timings shown in FIG. 8, the transition of the first drive pulse signal φH1 starts after the potentials of the second horizontal transfer section 32 and the third horizontal transfer section 33 which are on the downstream side are inverted, and then the charges from the first horizontal transfer section 31 on the upstream side are transferred to the branch section 34. As a result, the charges transferred to the branch section 34 can be transferred to the second horizontal transfer section 32 or the third horizontal transfer section 33 more securely.

In addition, the transition of the first drive pulse signal φH1 completes after the transition completion time point tc of the second drive pulse signals φHP1 and φHP2 which are applied to the transfer sections on the downstream side. For this reason, a possibility that a large amount of charges flow from the first horizontal transfer section 31 to the branch region 54 instantaneously and the charges are transferred to the unintended transfer section on the downstream side (the second horizontal transfer section 32 or the third horizontal transfer section 33) by mistake can be reduced. As described in the example shown in FIG. 8, the transfer time of the charges from the first horizontal transfer section 31 to the branch section 34 can be shortened by shortening the transition period of the first drive pulse signal φH1. However, if the slew rates of the first drive pulse signals φH1 and φH2, which are applied to the first horizontal transfer section on the upstream side, are high, a large amount of charges flow to the branch region 54 instantaneously during the potential transition period of the transfer sections on the downstream side. At that time, if the transition of the potentials of the transfer sections on the downstream side (the second horizontal transfer section 32 or the third horizontal transfer section 33) have not completed, there is a possibility that the charges are transferred to the unintended transfer section on the downstream side by mistake. However, the possibility that the charges are transferred by mistake can be reduced by setting the transition completion time point tb of the first drive pulse signal φH1 after the transition completion time point tc of the second drive pulse signals φHP1 and φHP2 applied to the transfer section on the downstream side.

As described above, by supplying the first drive pulse signals φH1 and φH2 and the second drive pulse signals φHP1 and φHP2 at the timings shown in FIG. 9, the charges transferred from the upstream side (the first horizontal transfer section 31) to the branch section 34 are not transferred to a transfer section on the downstream side (the second horizontal transfer section 32 or the third horizontal transfer section 33) other than the intended transfer section by mistake, but are transferred accurately even if the slew rates of the first drive pulse signals φH1 and φH2 are high.

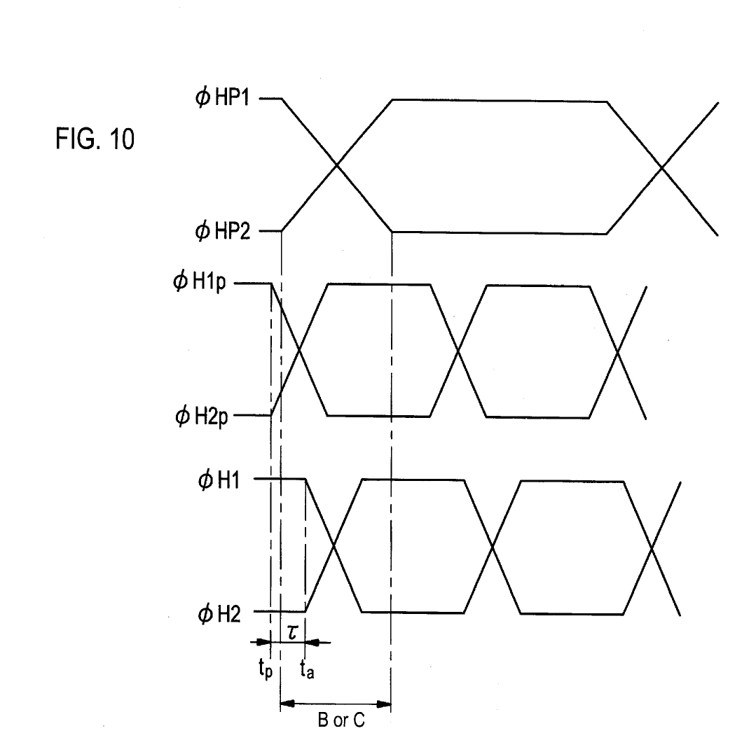

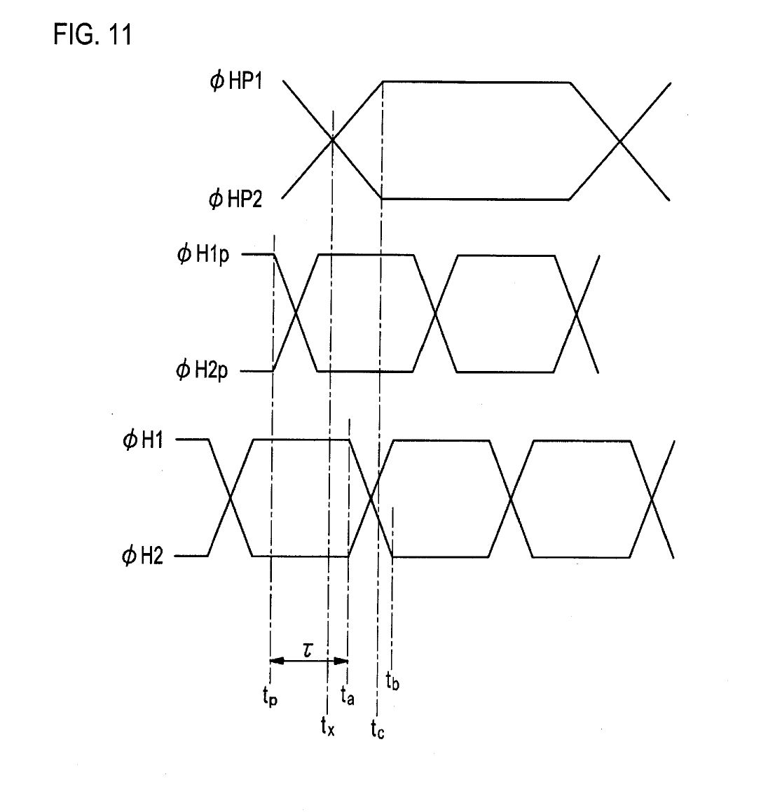

FIGS. 10 and 11 are graphs illustrating generation timings of the first drive pulse signals φH1 and φH2 in the drive section (not shown). As a length of the horizontal transfer section 30 (the first horizontal transfer section 31) becomes longer, a time constant due to an electrical resistance of the wiring for supplying the first drive pulse signals φH1 and φH2 and an electrostatic capacitance of the horizontal transfer electrodes become unignorable. As a result, in the actual electrodes, the transition start time point of the first drive pulse signals φH1 and φH2 would be delayed by the time constant from the transition start time point of the pulse signals φH1p and φH2p in a pulse generator of the drive section. Hence, a delay time r is measured in advance, and the transition start time point of the pulse voltages in the pulse generator of the drive section for supplying the first drive pulse signals φH1 and φH2 is set so as to be advanced by the delay time r. FIG. 10 corresponds to the drive pulse signals shown in FIGS. 5 and 6, and FIG. 11 corresponds to the drive pulse signals shown in FIG. 9. The transition start time point of the first drive pulse signals generated by the drive section (hereafter may be referred to as “generated first drive pulse signals”) φH1p and φH2p is determined in consideration of the delay time τ due to, for example, the resistance of the wiring for supplying the first drive pulse signals φH1 and φH2 to the horizontal transfer electrodes 61 and 62 which are disposed above the first horizontal transfer section 31.

In the example shown in FIG. 10, the generated first drive pulse signals φH1p and φH2p are generated so as to perform transition earlier than the transition start time point ta by the delay time τ so that the transition start time point ta of the first drive pulse signal φH1 supplied to the horizontal transfer electrodes 61 and 62 above the first horizontal transfer section 31 is within the transition period B or C of the second drive pulse signals φHP1 and φHP2. Although the transition completion time point of the first drive pulse signals φH1 and φH2 is also within the transition period B or C of the second drive pulse signals φHP1 and φHP2 in FIG. 10, the transition completion time may be after the transition period B or C.

In the example shown in FIG. 11, the generated first drive pulse signals φH1p and φH2p are generated earlier by the delay time τ so that the transition start time point ta of the first drive pulse signal φH1 supplied to the horizontal transfer electrodes 61 and 62 above the first horizontal transfer section 31 is between (i) the crossover time point tx between the second drive pulse signals φHP1 and φHP2 and (ii) the transition completion time point tc of the second drive pulse signals φHP1 and φHP2, and so that the transition completion time point tb of the first drive pulse signal φH1 is after the transition completion time point tc of the second drive pulse signals φHP1 and φHP2.

As described above, by generating the drive pulse signals in the drive section at the timings shown in FIG. 10 or FIG. 11, the delay time between the horizontal transfer electrodes 60 of the horizontal transfer section 30 and the drive section (not shown) can be corrected.

In the charge-transfer device described above, the potential of the branch region 54 serving as the channel region of the branch section 34 changes stepwise, that is, the potential is shallow on the upstream side and deep on the downstream side. However, the potential may change with a slope. In addition, the potential profile in the channel region 50 is changed by changing the impurity concentration of the channel region 50. However, the potential profile may also be changed by introducing impurities of different conductivity types, by changing the thickness of the gate insulation film, by changing the work function of the electrode or by dividing the electrode into plural portions and applying different voltages thereto.

Although the CCD charge-transfer apparatus in which charges are transferred through the branch portion is described above by taking the horizontal transfer section in an area sensor as an example, this kind of charge-transfer apparatus can also be used for the charge-transfer section of a line sensor or the charge-transfer sections of other devices, such as a shift register.

As described above, the present specification has disclosed at least the following matters.

The described charge-transfer apparatus for transferring charges through a branch includes a channel region, a plurality of charge transfer electrodes and a drive section. The channel region is formed on a semiconductor substrate. The plurality of charge transfer electrodes are provided continuously in an extending direction of the channel region above the channel region. The drive section supplies drive signals to the charge transfer electrodes. The channel region includes a first region, a branch region, a second region and a third region. The first region is on an upstream side in a charge transfer direction. The branch region is adjacent to the first region and is on a downstream side of the first region in the charge transfer direction. The second region and the third region are branched from the branch region. The branch region has a potential being shallow on the upstream side in the charge transfer direction and deep on the downstream side in the charge transfer direction. The drive section supplies first drive pulse signals, acting as two-phase clock pulse signals having opposite phases and a predetermined period, to the charge transfer electrodes above the first region. The drive section supplies a predetermined fixed voltage signal to the charge transfer electrodes above the branch region. The drive section supplies second drive pulse signals, having a period twice as long as the period of the first drive pulse signals, to the charge transfer electrodes above the second region and the charge transfer electrodes above the third region. The drive section supplies the second drive pulse signals having opposite phases to (i) the charge transfer electrodes above the second region adjacent to the charge transfer electrodes above the branch region and (ii) the charge transfer electrodes above the third region adjacent to the charge transfer electrodes above the branch region. When the charge in the first region is transferred to the branch region, a transition start time point of the first drive pulse signals is within a transition period of the second drive pulse signals.

With this charge-transfer apparatus, it is possible to prevent the charges, which are transferred from the upstream side, from being transferred to a branch path other than an intended branch path by establishing a relationship between the transition start time point of the drive pulse signals on the upstream side and the downstream side of the branch region, that is, by starting the transition of the drive pulse signals on the upstream side in the period between the transition start time point and the transition completion time point of the drive pulse signals on the downstream side.

In the described charge-transfer apparatus, when the charge in the first region is transferred to the branch region, the transition start time point of the first drive pulse signals is within a period between (i) a crossover time point between the second drive pulse signals and (ii) a transition completion time point of the second drive pulse signals. With this configuration, it is possible to reduce the risk of allowing the charges to be transferred to a branch path other than the intended branch path by mistake by changing the potential on the upstream side and by starting the flow of the charges to be transferred to the downstream side after the second drive pulse signals have crossed over and the potentials of the second region and the third region on the downstream side of the branch region have been inverted.

In the described charge-transfer apparatus, when the charge in the first region is transferred to the branch region, a transition completion time point of the first drive pulse signals is after a transition completion time point of the second drive pulse signals. With this configuration, it is possible to reduce the risk of allowing a large amount of charges to flow from the first region and to be distributed to a branch path other than the intended branch path by mistake in the middle of the transition of the drive pulse signals in the second region and the third region.

In the described charge-transfer apparatus, the drive section determines the transition start time point of the first drive pulse signals with considering a delay time due to an electrostatic capacitance caused by wiring for supplying the first drive pulse signals to the charge transfer electrodes above the first region, to generate the first drive pulse signals. With this configuration, it is possible to correct the delay time generated between the change in the potential of the transfer electrodes and the change in the potential of the drive section due to the electrostatic capacitance between the first region and the transfer electrodes above the first region and the resistance between the drive section and the transfer electrodes above the first region.

In the described charge-transfer apparatus, the potential of the branch region being shallow on the upstream side in the charge transfer direction and deep on the downstream side in the charge transfer direction is formed (i) by at least two regions being different in impurity concentration, (ii) by at least two regions being different in conductivity type, (iii) by a region in which an impurity concentration of a same conductivity type continuously changes, (iv) by at least two regions being different in thickness of a gate insulation film which is provided above the branch region, or (v) by dividing the electrodes above the branch region into at least two portions and by applying different DC voltages thereto. With this configuration, it is possible to improve the efficiency of signal charge transfer by forming a potential being high on the upstream side of the branch region and being low on the downstream side in the charge transfer direction.

In the described charge-transfer apparatus, a planar shape of the branch region includes a portion having an approximately triangular or trapezoidal shape becoming narrower in width from the upstream side to the downstream side in the charge transfer direction. With this configuration, it is possible to improve the efficiency of charge transfer.

The disclosed charge-transfer apparatus further includes detection sections and signal output sections. The detection sections detect the charges transferred from the second region and the charges transferred from the third region, as electrical signals. The signal output sections output the electrical signals detected by the detection sections, respectively.

The described imaging apparatus has the above-mentioned charge-transfer apparatus.

A drive method for driving a charge-transfer apparatus has been described. The charge-transfer apparatus includes a channel region and a plurality of charge transfer electrodes. The channel region is formed on a semiconductor substrate. The plurality of charge transfer electrodes are provided continuously in an extending direction of the channel region above the channel region. The channel region includes a first region, a branch region, a second region and a third region. The first region is on an upstream side in a charge transfer direction. The branch region is adjacent to the first region and is on a downstream side of the first region in the charge transfer direction. The second region and the third region are branched from the branch region. The branch region has a potential being shallow on the upstream side in the charge transfer direction and deep on the downstream side in the charge transfer direction. The drive method includes: supplying first drive pulse signals, acting as two-phase clock pulse signals having opposite phases and a predetermined period, to the charge transfer electrodes above the first region; supplying a predetermined fixed voltage signal to the charge transfer electrodes above the branch region; supplying second drive pulse signals, having a period twice as long as the period of the first drive pulse signals, to the charge transfer electrodes above the second region and the charge transfer electrodes above the third region; and supplying the second drive pulse signals, having opposite phases, to (i) the charge transfer electrodes above the second region adjacent to the charge transfer electrode above the branch region and (ii) the charge transfer electrodes above the third region adjacent to the charge transfer electrode above the branch region. When the charge in the first region is transferred to the branch region, a transition start time point of the first drive pulse signals is within a transition period of the second drive pulse signals.

In the described drive method, when the charge in the first region is transferred to the branch region, the transition start time point of the first drive pulse signals is within a period between (i) a crossover time point between the second drive pulse signals and (ii) a transition completion time point of the second drive pulse signals.

In the described drive method, when the charge in the first region is transferred to the branch region, a transition completion time point of the first drive pulse signals is after a transition completion time point of the second drive pulse signals.

The described drive method further includes determining the transition start time point of the first drive pulse signals with considering a delay time due to an electrostatic capacitance caused by wiring for supplying the first drive pulse signals to the charge transfer electrodes above the first region, to generate the first drive pulse signals.

With the exemplary embodiments of the present invention, charges can be distributed securely to the branch paths. Hence, the exemplary embodiments of the present invention are useful for a charge-transfer apparatus having branched dual-signal output passages. In addition, this kind of charge-transfer apparatus is useful for imaging apparatuses.

What is claimed is:

1. A charge-transfer apparatus for transferring charges through a branch, the apparatus comprising:
a channel region that is formed on a semiconductor substrate;
a plurality of charge transfer electrodes that are provided continuously in an extending direction of the channel region above the channel region; and
a drive section that supplies drive signals to the charge transfer electrodes, wherein the channel region includes
a first region on an upstream side in a charge transfer direction,
a branch region being adjacent to the first region and being on a downstream side of the first region in the charge transfer direction, and
a second region and a third region that are branched from the branch region,
the branch region has a potential being shallow on the upstream side in the charge transfer direction and deep on the downstream side in the charge transfer direction,
the drive section
supplies first drive pulse signals, acting as two-phase clock pulse signals having opposite phases and a predetermined period, to the charge transfer electrodes above the first region,
supplies a predetermined fixed voltage signal to the charge transfer electrodes above the branch region,
supplies second drive pulse signals, having a period twice as long as the period of the first drive pulse signals, to the charge transfer electrodes above the second region and the charge transfer electrodes above the third region, and
supplies the second drive pulse signals having opposite phases to (i) the charge transfer electrodes above the second region adjacent to the charge transfer electrodes above the branch region and (ii) the charge transfer electrodes above the third region adjacent to the charge transfer electrodes above the branch region, and
when the charge in the first region is transferred to the branch region, a transition start time point of the first drive pulse signals is within a transition period of the second drive pulse signals.

2. The charge-transfer apparatus according to claim 1, wherein when the charge in the first region is transferred to the branch region, the transition start time point of the first drive pulse signals is within a period between (i) a crossover time point between the second drive pulse signals and (ii) a transition completion time point of the second drive pulse signals.

3. The charge-transfer apparatus according to claim 1, wherein when the charge in the first region is transferred to the branch region, a transition completion time point of the first drive pulse signals is after a transition completion time point of the second drive pulse signals.

4. The charge-transfer apparatus according to claim 1, wherein the drive section determines the transition start time point of the first drive pulse signals with considering a delay time due to an electrostatic capacitance caused by wiring for supplying the first drive pulse signals to the charge transfer electrodes above the first region, to generate the first drive pulse signals.

5. The charge-transfer apparatus according to claim 1, wherein the potential of the branch region being shallow on the upstream side in the charge transfer direction and deep on the downstream side in the charge transfer direction is formed by at least two regions being different in impurity concentration.

6. The charge-transfer apparatus according to claim 1, wherein the potential of the branch region being shallow on the upstream side in the charge transfer direction and deep on the downstream side in the charge transfer direction is formed by at least two regions being different in conductivity type.

7. The charge-transfer apparatus according to claim 1, wherein the potential of the branch region being shallow on the upstream side in the charge transfer direction and deep on the downstream side in the charge transfer direction is formed by a region in which an impurity concentration of a same conductivity type continuously changes.

8. The charge-transfer apparatus according to claim 1, wherein the potential of the branch region being shallow on the upstream side in the charge transfer direction and deep on the downstream side in the charge transfer direction is formed by at least two regions being different in thickness of a gate insulation film which is provided above the branch region.

9. The charge-transfer apparatus according to claim 1, wherein the potential of the branch region being shallow on the upstream side in the charge transfer direction and deep on the downstream side in the charge transfer direction is formed by dividing the electrodes above the branch region into at least two portions and by applying different DC voltages thereto.

10. The charge-transfer apparatus according to claim 1, wherein a planar shape of the branch region includes a portion having an approximately triangular or trapezoidal shape becoming narrower in width from the upstream side to the downstream side in the charge transfer direction.

11. The charge-transfer apparatus according to claim 1, further comprising:
detection sections that detect the charges transferred from the second region and the charges transferred from the third region, as electrical signals; and
signal output sections that output the electrical signals detected by the detection sections, respectively.

12. A drive method for driving a charge-transfer apparatus, wherein
the charge-transfer apparatus includes
a channel region that is formed on a semiconductor substrate, and
a plurality of charge transfer electrodes that are provided continuously in an extending direction of the channel region above the channel region,
the channel region includes
a first region on an upstream side in a charge transfer direction,
a branch region being adjacent to the first region and being on a downstream side of the first region in the charge transfer direction, and
a second region and a third region that are branched from the branch region, and
the branch region has a potential being shallow on the upstream side in the charge transfer direction and deep on the downstream side in the charge transfer direction,
the method comprising:
supplying first drive pulse signals, acting as two-phase clock pulse signals having opposite phases and a predetermined period, to the charge transfer electrodes above the first region;
supplying a predetermined fixed voltage signal to the charge transfer electrodes above the branch region;
supplying second drive pulse signals, having a period twice as long as the period of the first drive pulse signals, to the charge transfer electrodes above the second region and the charge transfer electrodes above the third region; and
supplying the second drive pulse signals, having opposite phases, to (i) the charge transfer electrodes above the second region adjacent to the charge transfer electrode above the branch region and (ii) the charge transfer electrodes above the third region adjacent to the charge transfer electrode above the branch region, wherein
when the charge in the first region is transferred to the branch region, a transition start time point of the first drive pulse signals is within a transition period of the second drive pulse signals.

13. The drive method according to claim 12, wherein when the charge in the first region is transferred to the branch region, the transition start time point of the first drive pulse signals is within a period between (i) a crossover time point between the second drive pulse signals and (ii) a transition completion time point of the second drive pulse signals.

14. The drive method according to claim 12, wherein when the charge in the first region is transferred to the branch region, a transition completion time point of the first drive pulse signals is after a transition completion time point of the second drive pulse signals.

15. The drive method according to claim 8, further comprising:
determining the transition start time point of the first drive pulse signals with considering a delay time due to an electrostatic capacitance caused by wiring for supplying the first drive pulse signals to the charge transfer electrodes above the first region, to generate the first drive pulse signals.

16. An imaging apparatus comprising:
the charge-transfer apparatus according to claim 1.
